(19) United States
(12) Patent Application Publication
(10) Pub. No.: US 2025/0103787 A1
(43) Pub. Date: Mar. 27, 2025

(54) ROUTING METHOD AND SYSTEM

(71) Applicant: Samsung Electronics Co., Ltd., Suwon-si (KR)

(72) Inventors: Dongsu LEE, Suwon-si (KR); Wontae JEONG, Suwon-si (KR); Sungcheol PARK, Suwon-si (KR)

(73) Assignee: Samsung Electronics Co., Ltd., Suwon-si (KR)

(21) Appl. No.: 18/824,006

(22) Filed: Sep. 4, 2024

(30) Foreign Application Priority Data
Sep. 27, 2023 (KR) 10-2023-0130468
Nov. 30, 2023 (KR) 10-2023-0171829

(51) Int. Cl. G06F 30/3953

(52) U.S. Cl. CPC G06F 30/3953

(57) ABSTRACT

A routing method for an integrated circuit includes selecting design for testing (DFT) instances targeted by routing, routing positions respectively corresponding to the DFT instances, generating routing sequences for the DFT instances, deriving a start point and an end point based on indices included in each of the routing sequences, calculating a distance between the start point and the end point, and selecting a routing sequence as a result of the calculating of the distance.

### CROSS-REFERENCE TO RELATED APPLICATION

This application is based on and claims priority under 35 U.S.C. § 119 to Korean Patent Application No. 10-2023-0130468, filed on Sep. 27, 2023, and Korean Patent Application No. 10-2023-0171829, filed on Nov. 30, 2023, in the Korean Intellectual Property Office, the disclosures of each of which are incorporated by reference herein in their entireties.

### BACKGROUND

Various example embodiments relate to a routing method and/or system, and more particularly, to a routing connection method of a plurality of design for testing (DFT) instances.

In general, a system-on-chip (SoC) refers to a system that has several functions and is implemented by one semiconductor chip. To test logic circuits that are included in an SoC, DFT techniques have been used. DFT techniques may require or may use the placement/arrangement and routing of DFT instances.

### SUMMARY

Inventive concepts may provide a routing method capable of providing an improved or optimized routing sequence of design for testing (DFT) instances.

According to some example embodiments, there is provided a routing method.

The routing method includes selecting design for testing (DFT) instances targeted by routing, routing positions respectively corresponding to the DFT instances, generating routing sequences for the DFT instances, deriving a start point and an end point based on indices included in each of the routing sequences, calculating a distance between the start point and the end point, and selecting a routing sequence as a result of calculating the distance.

Alternatively or additionally according to some example embodiments, there is provided a system.

The system includes at least one processor and a memory storing instructions, when executed by at least one processor, cause the system to perform a routing method. The routing method includes selecting design for testing (DFT) instances targeted by routing, routing positions respectively corresponding to the DFT instances, generating routing sequences for the DFT instances, deriving a start point and an end point based on indices included in each of the routing sequences, calculating a distance between the start point and the end point, and selecting a routing sequence as a result of calculating the distance.

Alternatively or additionally according to some example embodiments, there is provided a non-transitory computer-readable storage medium including instructions.

The instructions, when executed by at least one processor, cause the at least one processor to perform a routing method, wherein the routing method includes selecting design for testing (DFT) instances, which are targeted by routing, and routing positions respectively corresponding to the DFT instances, generating routing sequences for the DFT instances, deriving a start point and an end point based on indices that are included in each of the routing sequences, calculating a distance between the start point and the end point, and selecting an optimized routing sequence as a result of calculating the distance.

### BRIEF DESCRIPTION OF THE DRAWINGS

Embodiments will be more clearly understood from the following detailed description taken in conjunction with the accompanying drawings in which:

FIG. 1A is a flowchart illustrating a method of designing a semiconductor integrated circuit, according to inventive concepts;

FIG. 1B is a diagram illustrating a routing structure in a register-transfer level (RTL) phase and in a gate-level netlist (GLN) phase;

FIG. 2 is a flowchart illustrating a routing method for a semiconductor integrated circuit, according to various example embodiments;

FIG. 3 is a flowchart illustrating a routing method for a semiconductor integrated circuit, according to various example embodiments;

FIG. 4A is a diagram of a routing structure in a layout of a semiconductor integrated circuit, according to a comparison example;

FIG. 4B is a diagram of a routing structure in a layout of a semiconductor integrated circuit, according to various example embodiments;

FIGS. 5A and 5B are diagrams illustrating a routing method for a layout of a semiconductor integrated circuit, according to various example embodiments;

FIG. 6 is a diagram illustrating a boundary setting method according to various example embodiments;

FIG. 7 is a diagram illustrating a distance calculating method according to various example embodiments;

FIG. 8A is a diagram illustrating a minimum distance calculating method according to a comparison example;

FIG. 8B is a diagram illustrating a minimum distance calculating method according to various example embodiments;

FIG. 8C is a diagram illustrating a minimum distance calculating method according to various example embodiments;

FIGS. 9A to 9G are diagrams respectively and specifically illustrating operations of setting a boundary corresponding to a block and calculating a minimum distance, according to various example embodiments;

FIG. 10 is a flowchart illustrating a method of fabricating an integrated circuit (IC), according to various example embodiments;

FIG. 11 is a block diagram illustrating a system-on-chip (SoC), according to various example embodiments; and

FIG. 12 is a block diagram illustrating a computing system including memory that stores a program, according to various example embodiments.

### DETAILED DESCRIPTION OF VARIOUS EMBODIMENTS

Hereinafter, embodiments of the inventive concept will be described in detail with reference to the accompanying drawings.

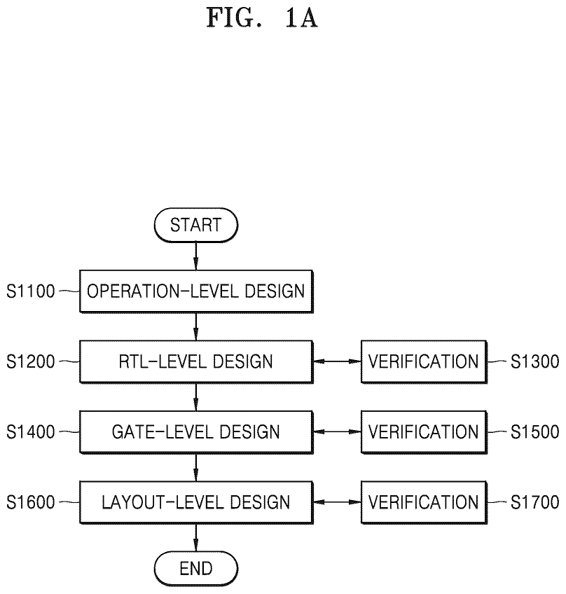

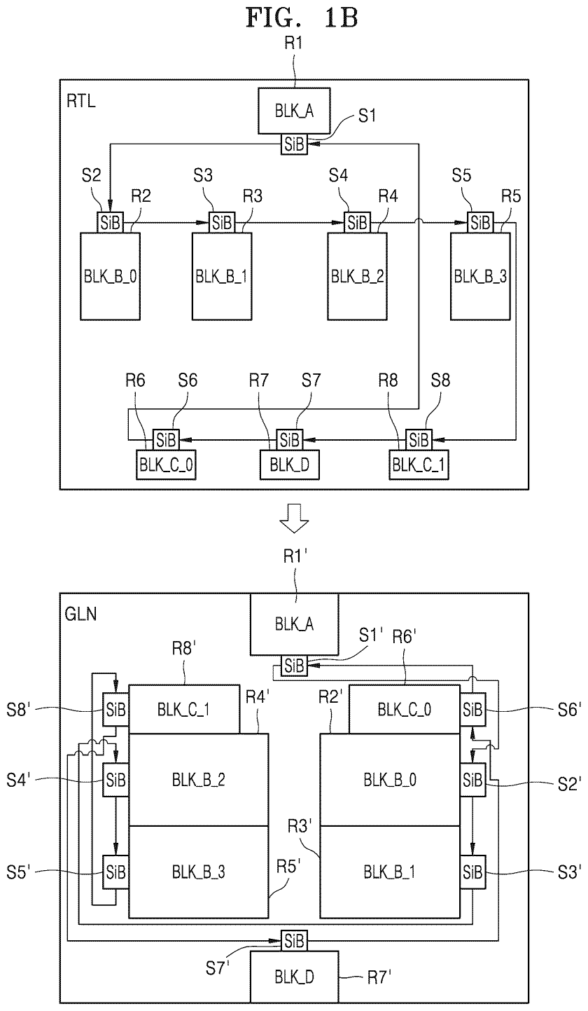

FIG. 1A is a flowchart illustrating a method of designing a semiconductor integrated circuit, according to inventive concepts.

Referring to FIG. 1A, in the method of designing a semiconductor integrated circuit, according to some example embodiments, an operation-level design corresponding to a functional design for the whole semiconductor integrated circuit is performed (S1100).

The operation-level design may also be referred to as an architecture design and/or as a high-level design. The high-level design may refer to depicting a semiconductor integrated circuit, which is a design target, at an algorithm level and to describing the semiconductor integrated circuit in a high-level language in a computer language. For example, a high-level language, such as the C programming language, may be used.

A register-transfer level (RTL) design for the semiconductor integrated circuit may be performed (S1200), and verification may be performed on the semiconductor integrated circuit having undergone the RTL design (S1300). In some example embodiments operations S1200 and S1300 may be iteratively performed; example embodiments are not limited thereto.

Circuits designed by the high-level design may be more specifically represented by RTL coding or simulation in operations S1200 and S1300. In addition, code generated by the RTL coding may be converted into a netlist and thus synthesized into the whole semiconductor integrated circuit. The synthesized schematic circuit may be verified by an RTL simulation tool and may undergo an accompanying adjustment process, e.g., depending on a verification result.

The RTL may be used to represent a coding style used in hardware description languages, which may help to effectively ensure that a code model is be synthesized (converted into actual logic functions) in a certain hardware platform, such as a field-programmable gate array (FPGA) and/or an application-specific integrated circuit (ASIC). There are a large number of hardware description languages used to generate the RTL code. The hardware description languages may include, for example, one or more of System Verilog, Verilog, VHDL, and the like.

A gate-level design for the semiconductor integrated circuit may be performed (S1400), and verification may be performed on the semiconductor integrated circuit having undergone the gate-level design (S1500).

The gate-level design may refer to depicting a semiconductor integrated circuit by logical connections between basic logic gates, such as one or more of an AND gate, an OR gate, a NAND gate, an NOR gate, an XOR gate, an AOI gate, etc., and by timing information. All signals are discrete signals and may each have only a logical value of 0, 1, X, or Z (or high-Z).

A layout-level design for the semiconductor integrated circuit may be performed (S1600), and verification may be performed on the semiconductor integrated circuit having undergone the layout-level design (S1700).

The layout-level design may also be referred to as a physical design. A layout design for implementing the logically completed semiconductor integrated circuit on a semiconductor substrate such as a wafer (for example, a silicon substrate and/or a silicon-nitride substrate and/or a gallium-arsenide substrate) may be performed.

For example, the layout design may be performed with reference to the schematic circuit synthesized in the high-level design and/or to the netlist corresponding to the schematic circuit. The layout design may include a routing procedure in which various standard cells or IP blocks (intellectual property blocks) provided by a cell library are placed and connected with each other according to prescribed design rules.

The cell library for the layout design may also include information about electrical properties such as one or more of operations, speeds, power consumption, and the like of the standard cells. The cell library for representing a specific gate-level circuit by a layout is defined in many or most of layout design tools. The layout may be a procedure of defining the shapes or sizes of patterns for configuring transistors and metal wiring lines, which are to be actually formed on a silicon substrate. For example, to actually form an inverter circuit on a silicon substrate, layout patterns, such as a PMOS, an NMOS, an N-WELL, a gate electrode, and metal wiring lines to be placed thereon, may be appropriately arranged.

A standard cell refers to a unit of an integrated circuit, which has a layout size satisfying rules, such as dynamically determined (or, alternatively predetermined rules and has a function, such as a dynamically determined (or, alternatively, predetermined) function. The standard cell may include an input pin and an output pin and may output a signal through the output pin by processing a signal received through the input pin. For example, the standard cells may correspond to basic cells, such as an AND, an OR, a NOR, and an inverter, complex cells, such as an OAI (OR/AND/INVERTER) and an AOI (AND/OR/INVERTER), and storage elements, such as a simple master-slave flip-flop and/or a latch.

In addition, routing may be performed on selected and placed standard cells. Specifically, routing with respect to upper wiring lines may be performed on the selected and placed standard cells. The standard cells may be connected to each other to be suited to a design through the routing procedure.

Depending on working methods that use layout editors, layout methods may be divided into a full-custom method in which a layout work is manually performed, an auto place & route (auto P&R) method that uses an automatic placement/wiring tool, and a semi-custom method that uses both the two methods set forth above.

In operation S1700, the layout may be verified regarding whether there are portions in violation of the design rules after the routing. Verification items may include one or more of design rule check (DRC) for verifying whether the layout is properly made in accordance with the design rules, electrical rule check (ERC) for verifying whether the layout is properly made without electrical disconnections in the layout, layout vs schematic (LVS) for verifying whether the layout is consistent with a gate-level netlist, and the like. In some cases, verification may include review such as manual review and acquiescence to various design rule violations; example embodiments are not limited thereto.

Although FIG. 1 illustrates operations S1100-S1700 in a particular order, example embodiments are not necessarily limited thereto. For example, in some example embodiments any two or more of operations S11000 to S1700 may be iteratively performed. For example, in some examples operation S1400 may be performed after operation S1200, or before operation S1200; similarly operation S1600 may be performed after operation S1200 or before.

According to various example embodiments, to test logic circuits in a system-on-chip (SoC) in which a system having several functions is implemented by one semiconductor chip, a design for testability or design for testing (DFT) technique may be used. According to various example embodiments, components placed for the DFT technique may be defined as DFT instances. As described below, the term “DFT instance” and the term “instance” may be interchangeably used. According to various example embodiments, DFT instances may each include one or more of MBIST, BSCAN, IJTAG, IEEE 1687 instances, but inventive concepts are not limited thereto. According to various example embodiments, for the connection between DFT instances inserted in the RTL-level design phase, a routing connection method between DFT instances using an A-star algorithm with consideration of a floorplan may be proposed. According to various example embodiments, a routing connection method between a plurality of DFT instances may be performed by using the A-star algorithm, thereby reducing routing congestion. This will be described in more detail with reference to the drawings described below.

FIG. 1B is a diagram illustrating a routing structure in the RTL phase and in a gate-level netlist (GLN) phase. The RTL phase of FIG. 1B may correspond to operation S1200 of FIG. 1A. The GLN phase of FIG. 1B may correspond to operation S1400 of FIG. 1A.

Referring to the RTL phase of FIG. 1B, a plurality of blocks R1, R2, R3, R4, R5, R6, R7, and R8 and SiB blocks S1, S2, S3, S4, S5, S6, S7, and S8 respectively corresponding thereto are illustrated.

According to various example embodiments, the plurality of blocks R1, R2, R3, R4, R5, R6, R7, and R8 may respectively correspond to DFT instances, and the SiB blocks S1, S2, S3, S4, S5, S6, S7, and S8 may respectively indicate routing positions accessible to the DFT instances respectively corresponding to the plurality of blocks R1, R2, R3, R4, R5, R6, R7, and R8. According to various example embodiments, each of the SiB blocks S1, S2, S3, S4, S5, S6, S7, and S8 may be a switch allowing a block connected to each thereof to be accessed.

According to various example embodiments, in the RTL phase of FIG. 1B, the plurality of blocks R1, R2, R3, R4, R5, R6, R7, and R8 may be placed without consideration of a floorplan for the connection between the plurality of blocks R1, R2, R3, R4, R5, R6, R7, and R8. According to various example embodiments, when the placement of the DFT instances is according to a SCAN structure, the stitching between SCAN cells may be performed after the synthesis of the RTL, and the SCAN cells may be placed depending on function logic. According to various example embodiments, when the placement of the DFT instances is according to Memory Built-In Self Test (MBIST), an MBIST interface may be placed adjacent to a memory instance, and a controller may be placed by considering the positions of MBIST interfaces.

In the case of such a placement, although an MBIST configuration in the RTL phase may be performed by grouping memories that perform functions, there may be a deterioration in timing for example caused by current-voltage (IR)) drop, for example when the memory instance is separated far from the MBIST instance after actual P&R, and in some cases layer overhead may be increased due to the introduction of a resource for overcoming the deterioration in timing.

Referring to the GLN phase of FIG. 1B, a result is illustrated in which a routing distance between the SiB blocks S1, S2, S3, S4, S5, S6, S7, and S8 configured as in the RTL phase of FIG. 1B is increased after actual P&R. Referring to the GLN phase of FIG. 1B, the layout in the RTL phase is not reflected as it is, and along with performing the gate-level design, the placement of a plurality of blocks R1′, R2′, R3′, R4′, R5′, R6′, R7′, and R8′ may vary and the placement of SiB blocks S1′, S2′, S3′, S4′, S5′, S6′, S7′ and S8′ respectively corresponding thereto may also vary.

For example, referring to FIG. 1B, a routing distance between SiB blocks configured in the RTL phase may be increased after actual P&R, thereby deteriorating the performance of a semiconductor chip. Routing congestion may occur due to the performance deterioration, and the routing congestion may act as a burden on timing signoff, and may deteriorate the performance of the overall semiconductor chip. According to various example embodiments, the routing congestion may occur when a DFT structure is generated by configuring the sequence of blocks in the initial phase without considering the floorplan derived along with the progress of milestones.

The configuration and sequence of the DFT instances designed in the RTL phase are fixed, and changing the configuration after synthesis may be impossible or at best require a lot of time and/or human (engineering) resources depending on characteristics of a task. Accordingly, the configuration of the DFT instances without considering the floorplan in the P&R phase may increase turnaround time (TAT) in the P&R phase, and this may act as an obstacle in performing the overall task. According to inventive concepts, there may be a good effect regarding the deterioration due to routing overhead as compared with the DFT configuration without considering routing. Alternatively or additionally, this may improve various properties such as one or more of the performance, power, area, and the like of an overall test and may reduce routing resources, thereby improving testability and reliability. When a technique proposed in the inventive concept is used, a good (e.g., an optimum) routing path may be provided for MBIST, IJTAG, Boundary Scan, or the like, which needs to be performed in the RTL design phase.

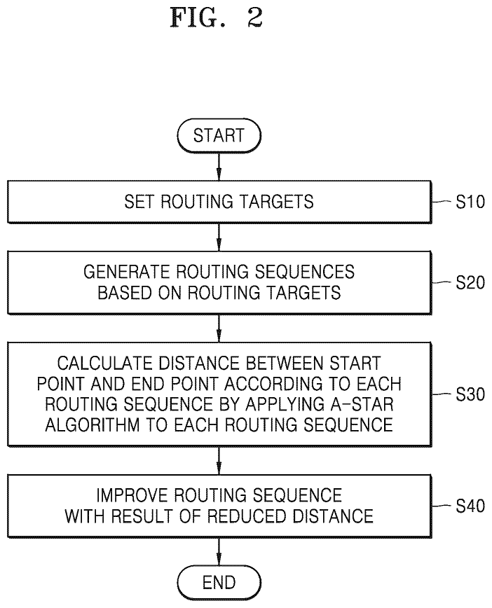

FIG. 2 is a flowchart illustrating a routing method for a semiconductor integrated circuit, according to various example embodiments.

Referring to operation S10 of FIG. 2, a routing target may be set. According to various example embodiments, the routing target may include a DFT instance. According to various example embodiments, the routing target may be set in a plural number.

Referring to operation S20 of FIG. 2, a plurality of routing sequences may be generated based on the routing target. According to various example embodiments, when a plurality of routing targets are set, all sequences allowed to be obtained by making combinations of the plurality of routing targets may be generated.

Referring to operation S30 of FIG. 2, the distance between a start point and an end point according to each of the plurality of routing sequences may be calculated by applying an algorithm such as an A* or A-star algorithm to each of the plurality of routing sequences. According to various example embodiments, when the number of routing sequences made in operation S20 is n, the A-star algorithm may be applied to each of the n routing sequences. Accordingly, n distances between a start point and an end point for each of the n routing sequences may be derived as a result.

As used herein, an A-star algorithm can be used to find the shortest path from a specified start point to a specified end point. As used herein, an A-star algorithm can be described as an informed search algorithm and/or a best-first search algorithm. As used herein, an A-star algorithm may operate by maintaining a tree of paths originating from the start node, and extending those paths one edge at a time until the end node is reached.

Referring to operation S40 of FIG. 2, a routing sequence may be improved or optimized with a result having a low such as the minimum distance in operation S30. For example, the routing sequence may be determined by using a result having the minimum distance from among pieces of result data, for example, a piece of result data having the minimum value.

According to inventive concepts, an improved or optimized routing path for a plurality of DFT instances may be derived by using an A-star algorithm. According to inventive concepts, the A-star algorithm may include computational functions including a first function for a range from the start point to a current position and a second function for a range from the current position to the end point. Inventive concepts may provide an improved or optimum routing sequence by allowing a result of the shortest path including a bypass to be derived for DFT instances by using the A-star algorithm.

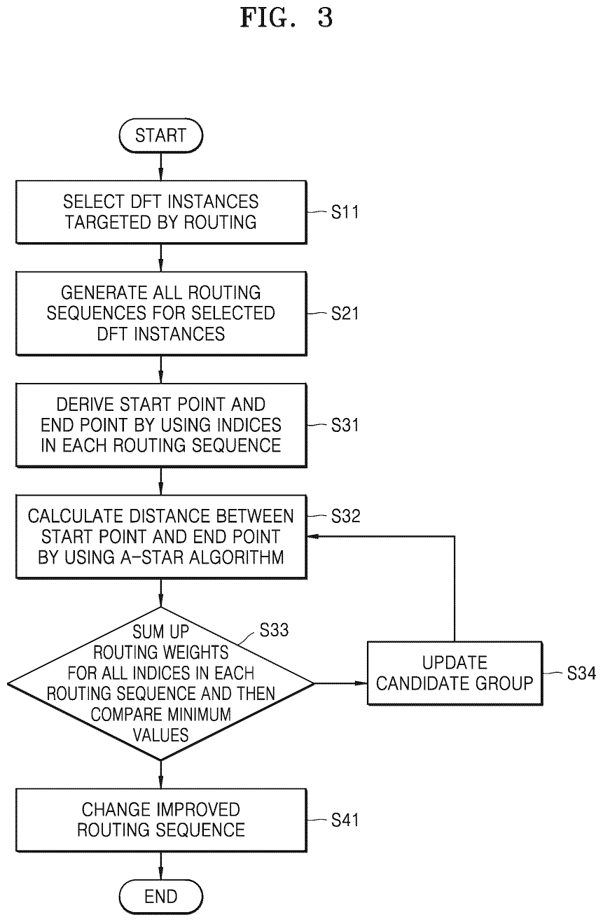

FIG. 3 is a flowchart illustrating a routing method for a semiconductor integrated circuit, according to various example embodiments.

Referring to operation S11 of FIG. 3, DFT instances targeted by routing may be selected. According to various example embodiments, the DFT instances targeted by routing may be provided based on floorplan information. According to various example embodiments, operation S11 of FIG. 3 may correspond to operation S10 of FIG. 2.

Referring to operation S21 of FIG. 3, all routing sequences for the DFT instances selected in operation S11 may be made. According to various example embodiments, operation S21 of FIG. 3 may correspond to operation S20 of FIG. 2.

Referring to operation S31 of FIG. 3, a start point or start node or source node and an end point or end node or sink node may be derived by using indices in each routing sequence. According to various example embodiments, in each of a plurality of routing sequences generated, the start point and the end point may have already been determined. According to various example embodiments, the start point and the end point of each of the plurality of routing sequences may be determined, for example, by a user and/or by another algorithm; example embodiments are not limited thereto. Referring to operation S31 of FIG. 3, only routing sequences satisfying determined conditions of the start point and the end point may be derived from among the routing sequences generated in operation S21, or all the routing sequences generated in operation S21 may have the same start point and the same end point. Alternatively, the routing sequences generated in operation S21 may be determined to have only the same start point.

Referring to operation S32 of FIG. 3, the distance between the start point and the end point may be calculated by using the A-star algorithm. According to various example embodiments, the respective minimum distances of paths passing through the plurality of DFT instances located between the start point and the end point may be calculated by using the A-star algorithm.

Referring to operation S33 of FIG. 3, routing weights for all the indices in each routing sequence may be summed up, and then, the comparison between minimum values may be performed. According to various example embodiments, all the indices in each routing sequence may be a concept including the start point, the end point, and the DFT instances located between the start point and the end point. According to various example embodiments, the summation of the routing weights for all the indices in each routing sequence may be performed, and this process may be performed on all the routing sequences. When the above process is performed on all the routing sequences, the routing method may proceed to operation S41, and when the above process is not performed on all the routing sequences, the routing method may proceed to operation S34 to update a candidate group. Referring to operation S34 of FIG. 3, the candidate group may be updated. Updating the candidate group may refer to updating the candidate group on which the A-star algorithm is to be performed. According to various example embodiments, the candidate group may correspond to one of the plurality of routing sequences. According to various example embodiments, operations S31, S32, S33, and S34 of FIG. 3 may correspond to operation S30 of FIG. 2.

Referring to operation S41 of FIG. 3, by repeating or iterating operations S31 to S34 described above, a routing sequence may be selected and optimized with a result having a reduced or the minimum distance between the start point and the end point. According to various example embodiments, operation S41 of FIG. 3 may correspond to operation S40 of FIG. 2.

According to inventive concepts, a routing method for a high-level abstraction layer for the access and control of a measuring device built in a semiconductor device may be proposed.

The routing method according to FIG. 2 or 3 may be performed by an application for converting a layout of a product including DFT instances into an array form, an application capable of performing the A-star algorithm on converted arrays, and an application capable of deriving an improved or optimum routing path. According to inventive concepts, a routing path improved or optimized for DFT instances even in the initial phase of design may be provided, thereby reducing layout overhead for DFT logic. According to inventive concepts, a routing sequence for embedded test logic may be provided, thereby efficiently or more efficiently arranging resources and/or reducing overhead in the P&R phase.

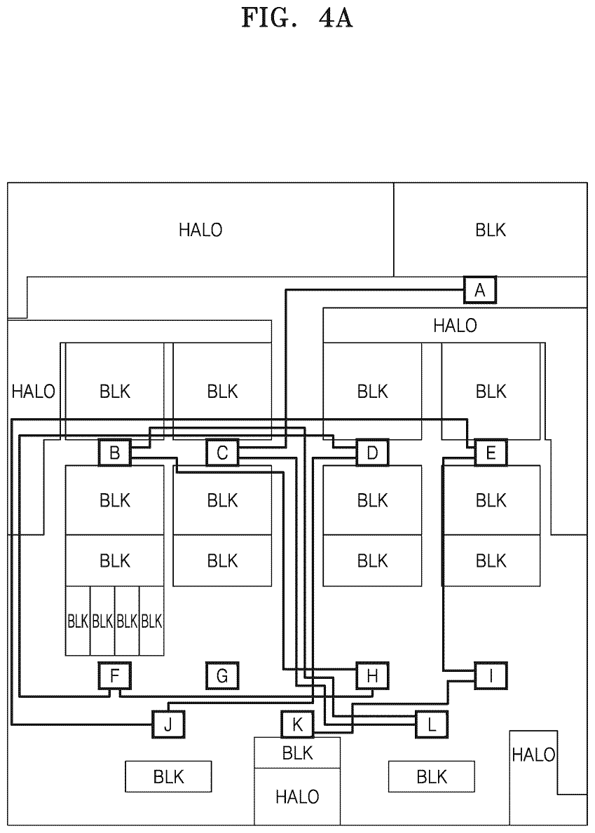

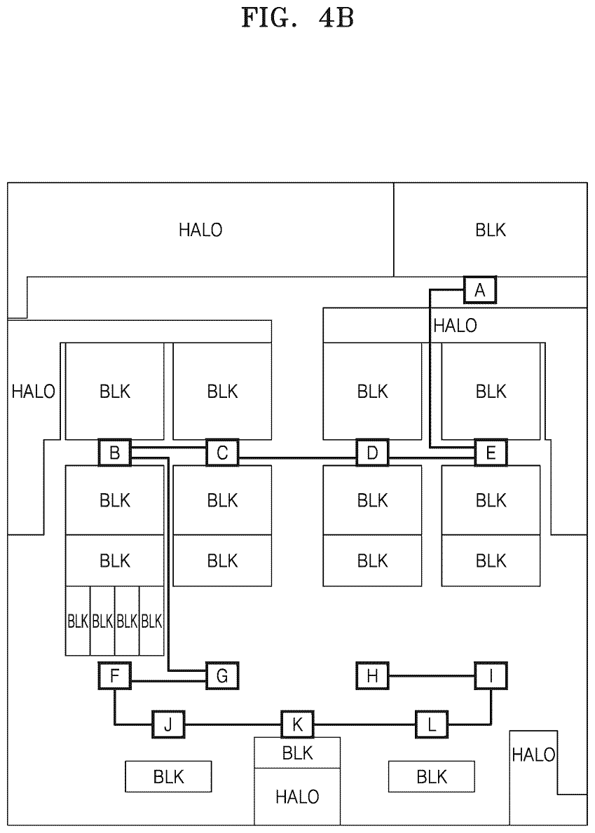

FIG. 4A is a diagram of a routing structure in a layout of a semiconductor integrated circuit, according to a comparison example. FIG. 4B is a diagram of a routing structure in a layout of a semiconductor integrated circuit, according to various example embodiments.

Referring to FIGS. 4A and 4B, an example of a layout diagram, in which a plurality of blocks BLK are arranged according to the respective placement positions, is illustrated.

In FIGS. 4A and 4B, it is illustrated that the placement positions of the plurality of blocks BLK and routing positions A, B, C, D, E, F, G, H, I, J, K, and L respectively corresponding to the plurality of blocks BLK are the same between FIGS. 4A and 4B. FIGS. 4 A and 4B are different from each other in a routing connection sequence between the plurality of blocks BLK. According to various example embodiments, the plurality of blocks BLK may respectively include DFT instances. According to various example embodiments, the routing positions A, B, C, D, E, F, G, H, I, J, K, and L capable of connecting the DFT instances to each other may be respectively placed in the vicinity of the blocks BLK. According to various example embodiments, the placement positions of the plurality of blocks BLK and the routing positions A, B, C, D, E, F, G, H, I, J, K, and L respectively corresponding to the plurality of blocks BLK may be information that is included in a floorplan.

FIG. 4A illustrates the routing structure in the layout of the semiconductor integrated circuit, according to the comparison example, and when the routing connection sequence of the DFT instances is not separately designated, the DFT instances may be connected to each other by a default value of a simulation tool. According to various example embodiments, the DFT instances may be connected to each other according to the alphabetical sequence. Referring to FIG. 4A, because the DFT instances targeted by routing respectively have the routing positions A, B, C, D, E, F, G, H, I, J, K, and L, the DFT instances may be routing-connected to each other in the sequence of A-B-C-D-E-F-G-H-I-J-K-L according to the alphabetical sequence.

When routing is performed as shown in FIG. 4A, because the floorplan is not considered, a result of the routing may impose a burden on timing signoff and/or may deteriorate the performance of the overall semiconductor chip.

FIG. 4B is a diagram of a routing structure in a layout of a semiconductor integrated circuit, according to various example embodiments.

Referring to FIG. 4B, it may be confirmed that routing congestion improves as compared with FIG. 4A. According to various example embodiments, routing connection between DFT instances may be performed according to a routing sequence derived by using floorplan information and by using the A-star algorithm. By doing this, congestion in the connection between the DFT instances after the P&R phase may be reduced and thus improve turn-around time (TAT), and the performance of a semiconductor chip may improve due to a reduction in routing overhead.

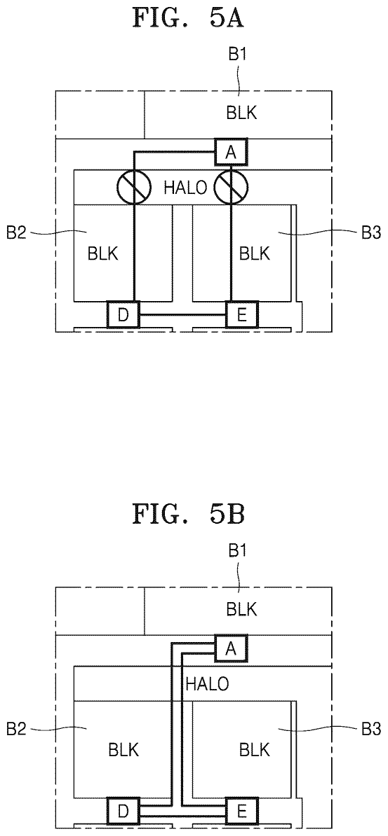

FIGS. 5A and 5B are diagrams illustrating a routing method in a layout of a semiconductor integrated circuit, according to various example embodiments.

FIGS. 5A and 5B are diagrams illustrating a method capable of performing connection between respective routing target regions of DFT instances. Referring to FIGS. 5A and 5B, a routing position A of a first block B1, a routing position D of a second block B2, and a routing position E of a third block B3 are illustrated.

Referring to FIG. 5A, an example is illustrated in which a routing connection is performed through the second block B2 to connect the routing position A of the first block B1 with the routing position D of the second block B2, and in which a routing connection is performed through the third block B3 to connect the routing position A of the first block B1 with the routing position E of the third block B3. However, because the fact that the routing nature not allowing each of the blocks (that is, B1, B2, and B3) to be traversed is not considered in the above routing connection, the above routing connection may correspond to an impossible connection structure.

Referring to FIG. 5B, to connect the routing position A of the first block B1 with the routing position D of the second block B2, a routing connection is performed by using a routing path between the second block B2 and the third block B3 such that the second block B2 is not traversed. To connect the routing position A of the first block B1 with the routing position E of the third block B3, a routing connection is performed by using a routing path between the second block B2 and the third block B3 such that the third block B3 is not traversed.

The routing method according to inventive concepts may include a function of bypassing a boundary of each of the blocks (that is, B1, B2, and B3). According to various example embodiments, the process of performing the A-star algorithm according to inventive concepts includes the function of bypassing the boundary of each of the blocks (that is, B1, B2, and B3), and thus, DRC may be prevented.

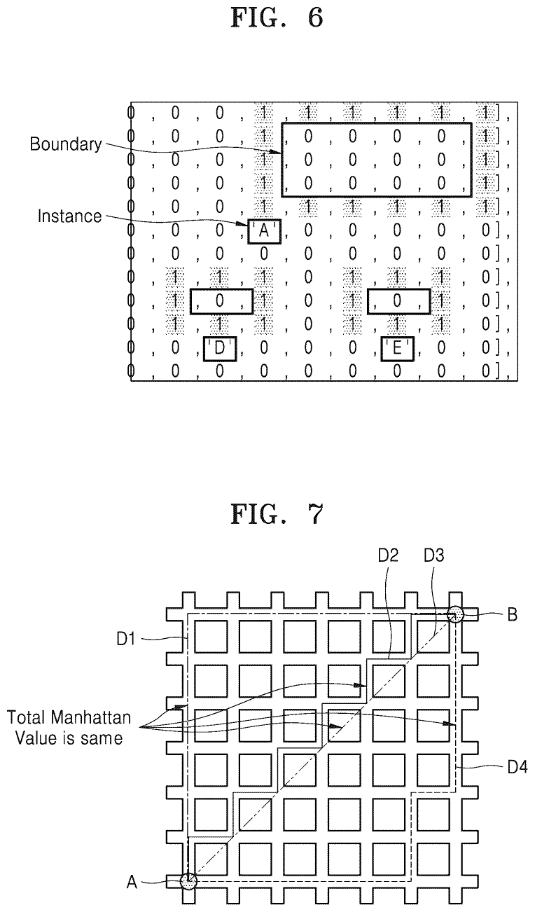

FIG. 6 is a diagram illustrating a boundary setting method according to various example embodiments.

According to various example embodiments, FIG. 6 may illustrate a logic configuration when blocks are converted into an array form by using floorplan information. Referring to FIG. 6, portions indicated by ‘0’ may refer to regions capable of being routed, and portions indicated by ‘l’ may refer to regions not capable of being routed. Example embodiments are not limited to ‘0’ and ‘1’ as above; for example, other alphanumeric characters or symbols may be used to indicate regions of capable or not capable of being routed. According to various example embodiments, a region generated by concatenating the portions indicated by ‘1’ with each other may correspond to a block. According to various example embodiments, the portions indicated by ‘l’ and forming a closed region may refer to a boundary region. The regions indicated by alphabets in FIG. 6 may refer to routing positions of DFT instances, respectively.

For example, referring to FIG. 6, it may be confirmed that three boundary regions may be formed in total and DFT instances (that is, A, D, and E) respectively corresponding thereto are shown. According to various example embodiments, the array of FIG. 6 may be a result of converting the layout of the floorplan shown in FIGS. 5A and 5B.

According to various example embodiments, a boundary may be designated for a region not allowed to be intruded. According to various example embodiments, a boundary may be designated when there is logic corresponding to a target to be protected in a block, or a boundary may be designated for a path not allowed to pass through. According to inventive concepts, an optimum path may be calculated by bypassing a region designated as a boundary.

FIG. 7 is a diagram illustrating a distance calculating method according to various example embodiments.

According to inventive concepts, as a method of calculating a small or the minimum distance from a point A to a point B, the Manhattan distance method (or the taxicab distance metric) may be used.

According to various example embodiments of FIG. 7, four paths may be configured between the point A and the point B. The respective distances of a first path D1, a second path D2, and a fourth path D4 according to the Manhattan distance method may be equal to each other. According to various example embodiments, assuming that the coordinate of the point A is (X1, Y1) and the coordinate of the point B is (X2, Y2), the minimum distance between the point A and the point B may be determined by the following expression.

$$\vert X 1 - X 2 \vert + \vert Y 1 - Y 2 \vert$$

Therefore, in the case where the coordinate of the point A and the coordinate of the point B have been determined, no matter which path is used, the minimum distance according to the Manhattan distance method may have the same value.

According to various example embodiments of FIG. 7, the shortest path from the point A to the point B may be the third path D3. The minimum distance according to the third path D3 may be a distance calculated by the Euclidean distance method. A Euclidean distance may be the shortest distance between the point A to the point B. However, in a method according to inventive concepts, because the characteristic of metal routing in a semiconductor chip needs to be considered, the minimum distance may be searched for by using a Manhattan distance.

In the method according to inventive concepts, distance exploration may be performed in four directions (or four cardinal and orthogonal directions), that is, upward, downward, leftward, and rightward directions, by taking into consideration the characteristic of metal routing. By doing this, a routing sequence considering the characteristic of metal routing may be provided.

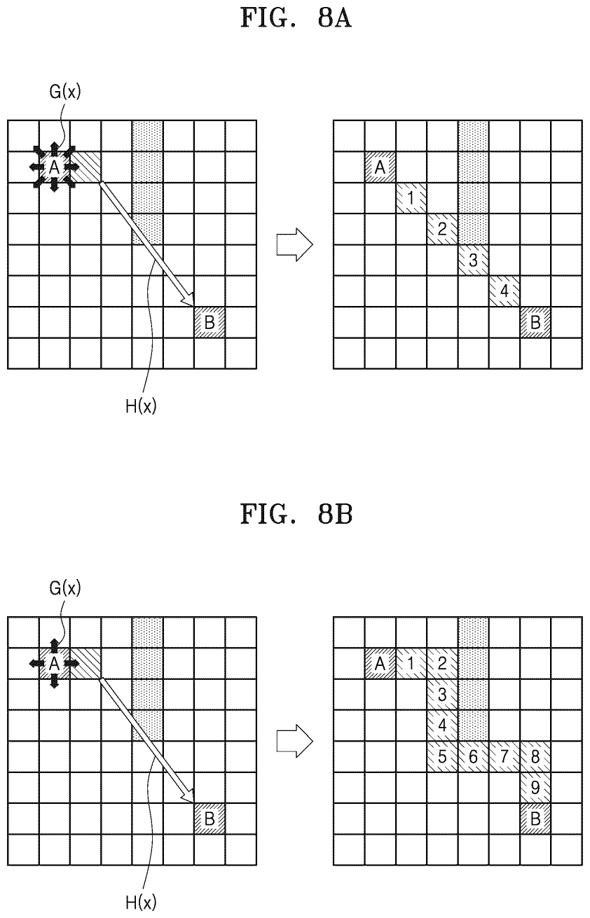

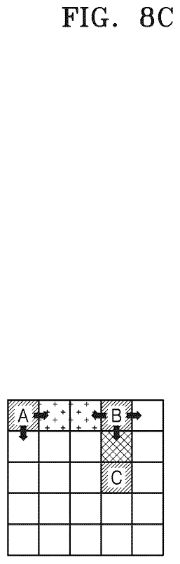

FIG. 8A is a diagram illustrating a minimum distance calculating method according to a comparison example, and FIG. 8B is a diagram illustrating a minimum distance calculating method according to various example embodiments.

Referring to FIGS. 8A and 8B, routing positions corresponding to DFT instances may be A and B, respectively, and it may be premised to try to find the minimum distance from A to B. According to inventive concepts, the minimum distance from A to B may be searched for by using the A-star algorithm.

Herein, the A-star algorithm may be or include or be included in a graph search algorithm. The A-star algorithm may be an algorithm for finding the shortest path from a start point to an end point in a given graph. The A-star algorithm may perform searching at a high speed by selecting the most promising node in a given circumstance. According to various example embodiments, the A-star algorithm includes a combination of Dijkstra's algorithm and a best-first search algorithm, and may calculate two values, that is, a value of G(x) and a value of H(x), for each node.

According to various example embodiments, the value of G(x) (cost-to-come) is a first function and may refer to an actual cost for a path from a start point to a current node. This value may be calculated based on the distance, time, cost, or the like from the start point to the current node. According to various example embodiments, the value of H(x) (heuristic) is a second function and may represent an estimated cost for a path from the current node to the end point. This value may be calculated by a heuristic function and may be less than an actual shortest-path cost. The heuristic function may be used to predict a path and estimate cost.

FIG. 8A is an example of a minimum-distance calculating method according to a comparison example and may be an example of using the Euclidean distance as the heuristic function. FIG. 8B is a diagram illustrating a minimum-distance calculating method according to various example embodiments and may be an example of using the Manhattan distance as the heuristic function. The Manhattan distance may be defined as a sum of vertical and horizontal movement distances between two points, and the Euclidean distance may be calculated based on the Pythagorean theorem. According to various example embodiments, the minimum distance to the end point may be calculated by using the Manhattan distance as the heuristic function with consideration of a layout of a metal layer.

According to various example embodiments, the A-star algorithm may find the end point by calculating a value of F(x), which is a final value, by summing up the value of G(x) and the value of H(x) of each node. The A-star algorithm searches for a node having the smallest value of F(x), and when the node that is being searched for reaches the end point, the A-star algorithm determines that the shortest path is found and is terminated. According to the A-star algorithm, the node having the smallest value of F(x) may be searched for first by using a priority queue. By doing this, a search process may be efficiently performed, and an unnecessary path may not be searched for.

Referring to FIGS. 8A and 8B, when moving one space by one space is assumed in deriving the shortest path from the position A to the position B, the distance from the position A to a current position may correspond to G(x), and the distance from the current position to the position B may correspond to H(x). Next, the A-star algorithm may be performed again at the minimum value of the values of F(x) according to movement directions and may be terminated with marking a path taken for movement when finally reaching the point B.

For example, according to the minimum-distance calculating method of FIG. 8B according to various example embodiments, position-movement of 9 spaces may be performed from the position A to the position B, and the A-star algorithm may be performed every time the movement of each space is performed. Alternatively or additionally, the value of F(x) may be calculated at each space, and movement may be performed by designating a path allowing the value of F(x) to be minimum as the next path. Therefore, the minimum distance from the position of each space to the end point may be calculated.

FIG. 8C is a diagram illustrating a minimum-distance calculating method according to various example embodiments.

According to various example embodiments, A, B, and C, which are a plurality of routing positions respectively corresponding to a plurality of DFT instances, are illustrated. Here, a start point and an end point may be determined in advance. According to various example embodiments, the start point may be determined to be A, and the end point may be determined to be C.

A routing sequence capable of passing through all the plurality of DFT instances may be generated according to determining the start point and the end point. According to FIG. 8C, the routing sequence generated according to determining the start point and the end point to be respectively A and C may be A-B-C.

Accordingly, to determine the minimum distance from A to B, the A-star algorithm may be used, and to determine the minimum distance from B to C, the A-star algorithm may be used.

To determine the minimum distance from A to B, a route causing F(x) to be minimum may be determined by calculating F(x) at each of the spaces that are in the route from A to B, and to determine the minimum distance from B to C, a route causing F(x) to be minimum may be determined by calculating F(x) at each of the spaces that are in the route from B to C.

In the process of performing the A-star algorithm, a candidate for the next coordinate may be selected at the current coordinate by using the function G(x) in four directions, that is, upward, downward, leftward, and rightward directions, during path exploration. This may be because, in a layout of a semiconductor chip, the connection between metals may be performed vertically and horizontally and the diagonal connection between metals is impossible. According to inventive concepts, a computational technique considering the characteristic of metal layers allowing vertical or horizontal routing to be performed may be used.

For example, according to inventive concepts, the A-star algorithm may be used for the routing exploration of DFT instances configured in the RTL phase, and a routing sequence of the shortest path may be provided by using the Manhattan distance for a computational function of the A-star algorithm.

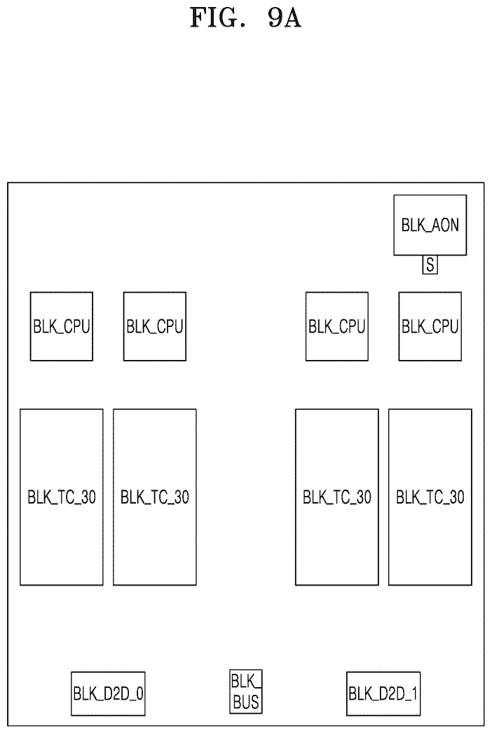

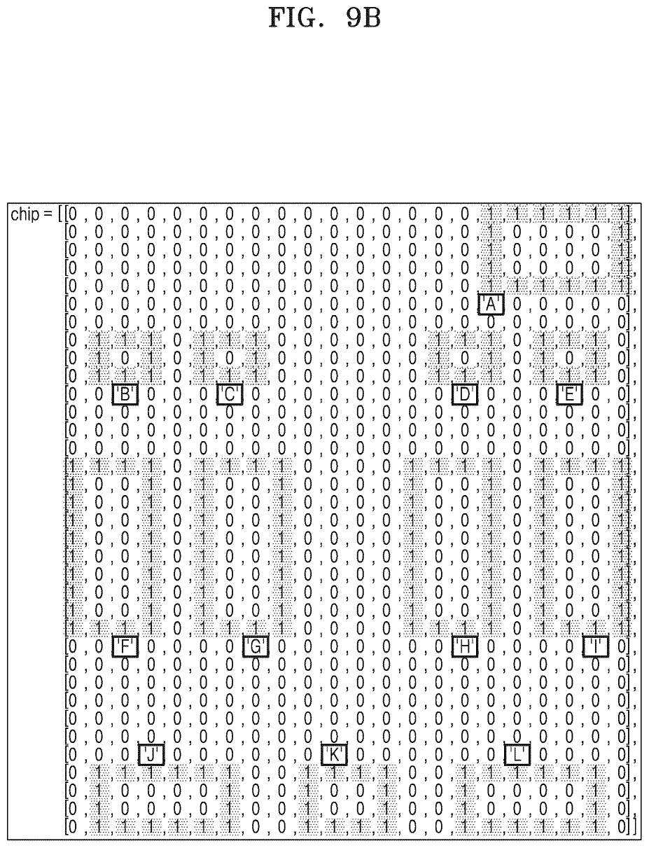

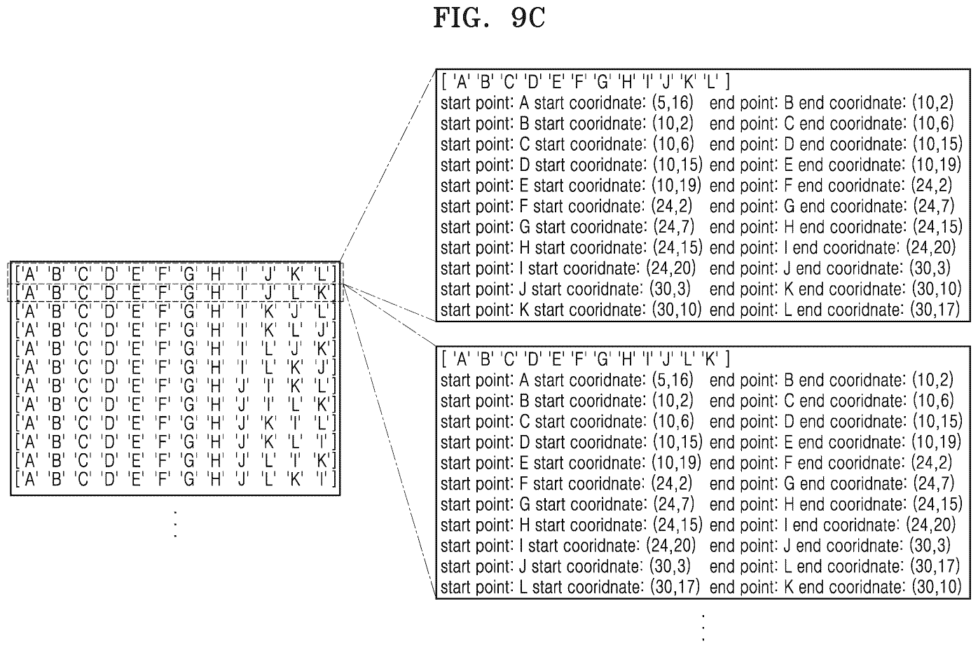

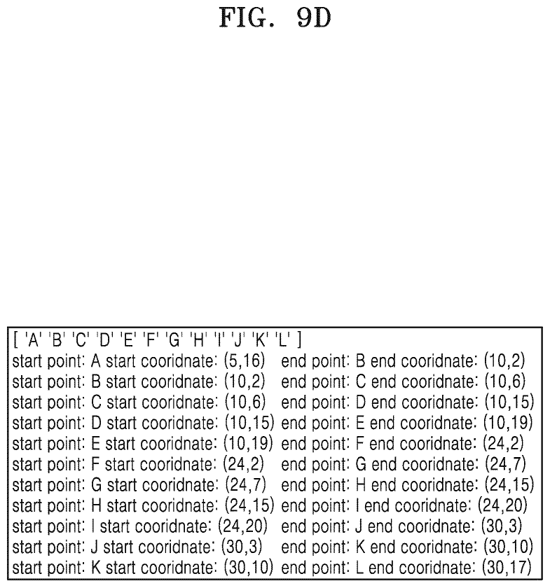

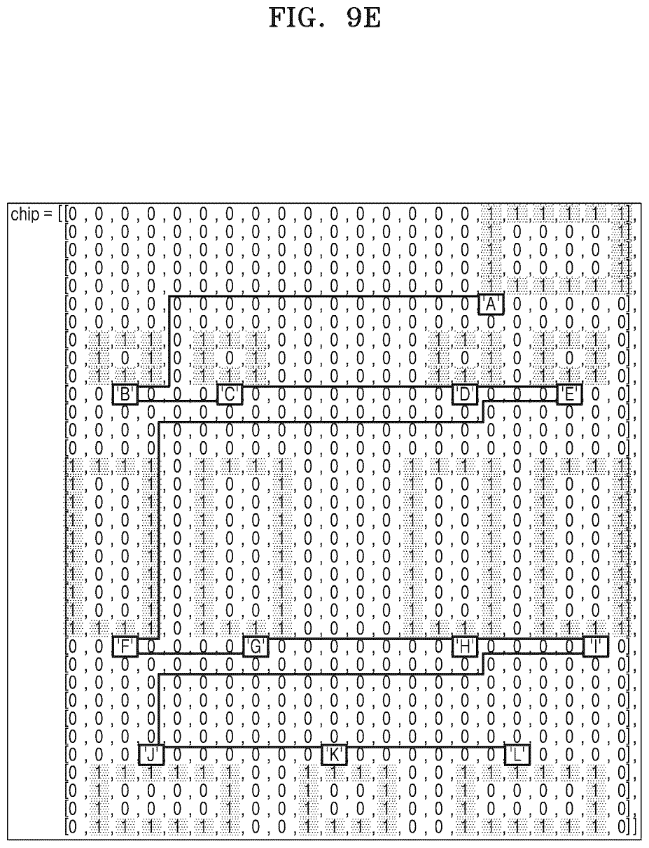

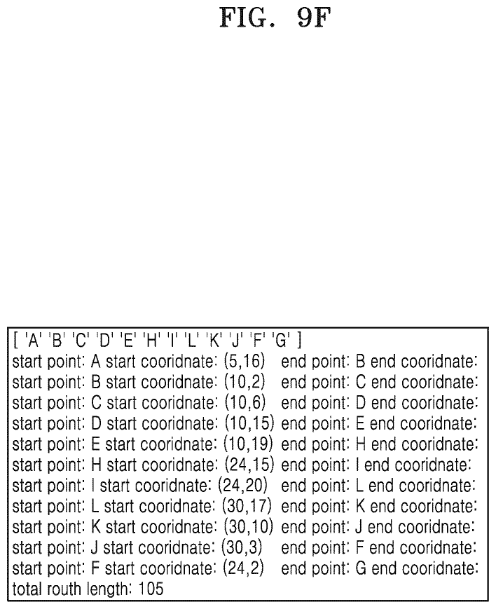

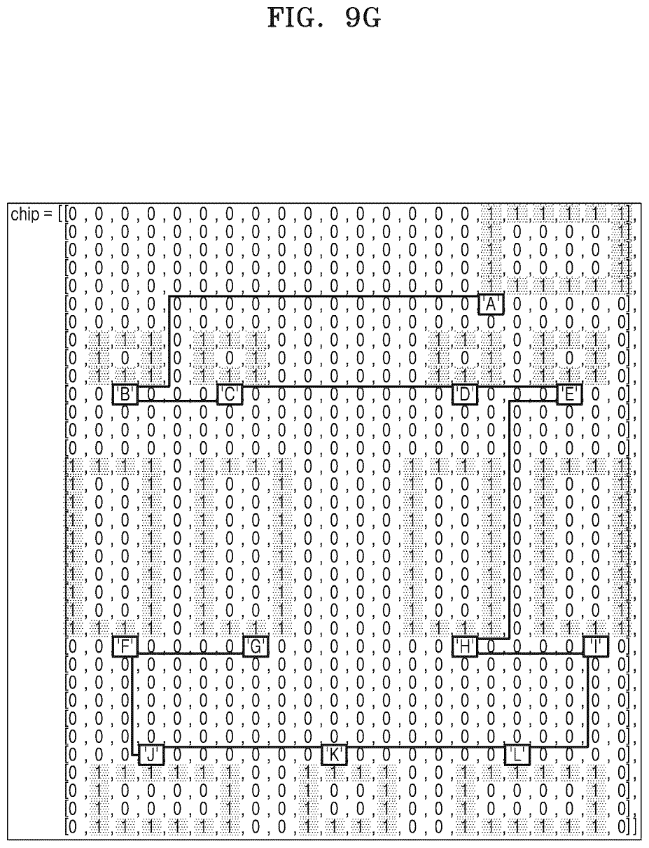

FIGS. 9A to 9G are diagrams respectively and specifically illustrating operations of setting a boundary corresponding to a block and calculating the minimum distance, according to various example embodiments.

Referring to FIG. 9A, a configuration is illustrated in which blocks respectively corresponding to a plurality of DFT instances are placed. According to various example embodiments, a placement structure of the blocks may be according to floorplan information of a semiconductor chip. According to various example embodiments, DFT instances requiring routing from among the plurality of DFT instances configured in the semiconductor chip may be determined. According to various example embodiments, because the plurality of DFT instances may also include DFT instances requiring no routing, the process of determining the DFT instances requiring routing from among the plurality of DFT instances may be performed in advance.

Referring to FIG. 9B, an example of implementing the placement structure corresponding to FIG. 9A into coordinates is illustrated. According to various example embodiments, points, at which the DFT instances selected to require routing in the floorplan of the semiconductor chip in FIG. 9A are to be located, may be implemented into coordinates. Referring to FIG. 9B, the blocks may be boundary-processed to correspond to the plurality of DFT instances, and routing positions respectively corresponding to the plurality of DFT instances may be implemented by alphabets. According to various example embodiments, all the DFT instances may be implemented into coordinates in an array form and may thus constitute data to undergo the A-star algorithm that is to be subsequently performed. Referring to FIG. 9B, a total of 12 routing positions A, B, C, D, E, F, G, H, I, J, K, and L and blocks respectively corresponding thereto are illustrated.

Referring to FIG. 9C, a routing position as a start point and a routing position as an end point may be determined from among the plurality of routing positions having been implemented into the coordinates. According to various example embodiments, routing candidate lists may be configured by permutating all the remaining routing positions except for the start point and the end point. Referring to FIG. 9C, an example of enumerating possible sequences of all the routing positions when the position A is taken as the start point and calculating the minimum distance for each of the sequences is illustrated.

According to various example embodiments, when the routing sequence is set to the sequence of A, B, C, D, E, F, G, H, I, J, K, and L, to determine the minimum distance according to the corresponding sequence, each of the minimum distance between A and B, the minimum distance between B and C, the minimum distance between C and D, the minimum distance between D and E, the minimum distance between E and F, the minimum distance between F and G, the minimum distance between G and H, the minimum distance between H and I, the minimum distance between I and J, the minimum distance between J and K, and the minimum distance between K and L may be calculated by using the A-star algorithm.

According to various example embodiments, when the routing sequence is set to the sequence of A, B, C, D, E, F, G, H, I, J, L, and K, to determine the minimum distance according to the corresponding sequence, each of the minimum distance between A and B, the minimum distance between B and C, the minimum distance between C and D, the minimum distance between D and E, the minimum distance between E and F, the minimum distance between F and G, the minimum distance between G and H, the minimum distance between H and I, the minimum distance between I and J, the minimum distance between J and L, and the minimum distance between L and K may be calculated by using the A-star algorithm.

For example, as such, the A-star algorithm may be performed on a DFT instance of the start point and a first DFT instance configured in each of the routing candidate lists, thereby calculating the minimum distance for the start point and the first DFT instance. When DFT instances are included in a routing candidate list after the configuration of the routing candidate list, the A-star algorithm may be performed on all the DFT instances recursively included in the routing candidate list, thereby searching for the shortest routing path. Next, the procedure described above may be performed on all the routing candidate lists, and then, the procedure may be terminated with deriving a routing candidate list having the shortest routing path.

FIGS. 9D and 9E illustrate an example of calculating the minimum distance for a candidate group and showing a routing path according to the calculation of the minimum distance, according to various example embodiments.

FIGS. 9F and 9G illustrate an example of showing the shortest routing path and the minimum distance, which are derived based on a result of performing the A-star algorithm on all the routing candidate lists, according to various example embodiments. When the example of FIGS. 9D and 9E is compared with the example of FIGS. 9F and 9G, it may be confirmed that the minimum distance in the example of FIGS. 9F and 9G is less than the minimum distance in the example of FIGS. 9D and 9E, and that the routing path shown in FIG. 9G is an optimum routing path.

According to inventive concepts, a burden in the placement and routing of DFT instances in the P&R phase may be reduced, and TAT may improve. The inventive concept may relate to the routing of DFT instances for testing inside a semiconductor chip, and according to inventive concepts, the A-star algorithm may be used and a calculation technique using the Manhattan distance in an evaluation function of the A-star algorithm may be used. When the A-star algorithm is applied to inventive concepts, a function of bypassing regions that are to be protected is included in the A-star algorithm, and the Manhattan distance, which is a heuristic function having a characteristic of four-direction movement considering the routing characteristic of metal layers, may be used.

According to inventive concepts, because optimized routing for DFT instances is provided in the initial phase of design, time for product development may be saved by saving time taken for devising a DFT structure upon designing a product, and time and cost required in a final test process may be reduced through improved or optimum routing in a tile structure including a large number of cores or computation devices used for high-performance computing (HPC) and artificial intelligence (AI) products and the like.

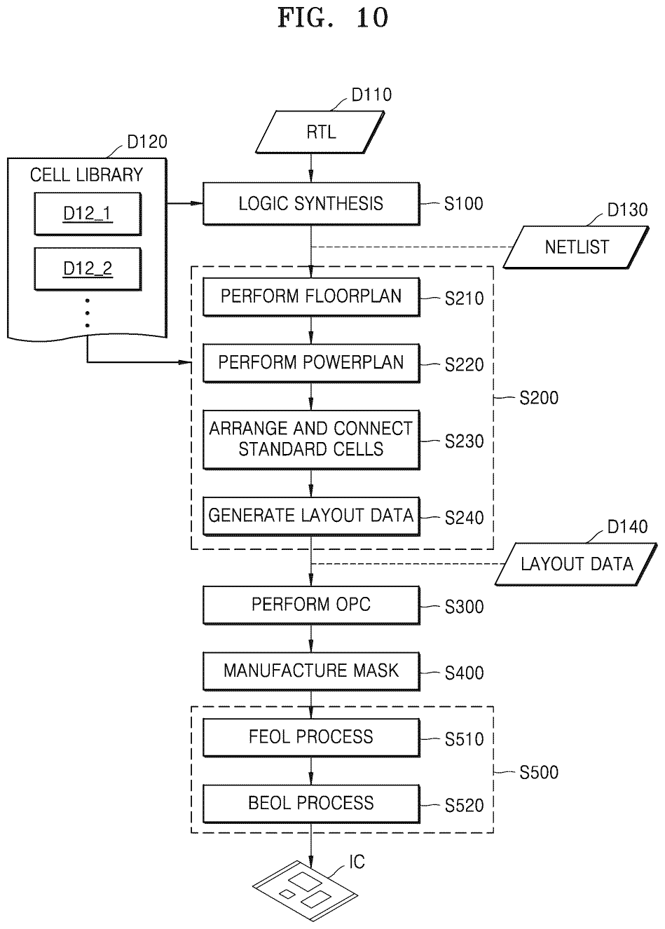

FIG. 10 is a flowchart illustrating a method of fabricating an integrated circuit (IC), according to various example embodiments.

A cell library (or standard cell library) D120 may include information about cells, for example, function information, characteristic information, layout information, and the like. As shown in FIG. 10, the cell library D120 may include pieces of data (that is, D12_1, D12_2, and the like) respectively defining a plurality of cell groups. For example, first data D12_1 may define a cell group including logic cells, and second data D12_2 may define a cell group including a filler cell. A standard cell may include a logic cell providing a Boolean logic function or a storage function. The standard cell may include a filler cell and/or a dummy cell that do not contributing to computations of the IC. Standard cells may respectively have different heights. The standard cells may respectively have different cell widths depending on the types thereof.

In operation S100, logic synthesis for generating netlist data D130 from RTL data D110 may be performed.

For example, a semiconductor design tool (for example, a logic synthesis tool) may generate the netlist data D130 including a bitstream or a netlist by performing logic synthesis from the RTL data D110 with reference to the cell library D120, the RTL data D110 being written in a hardware description language (HDL), such as one or more of VHSIC Hardware Description Language (VHDL) and Verilog.

In operation S200, generating layout data D140 from the netlist data D130 may be performed. As shown in FIG. 10, operation S200 of generating the layout data D140 may include a plurality of operations S210, S220, S230, and S240.

In operation S210, an electronic design automation (EDA) tool may perform floorplan according to floorplan rules. For example, the floorplan includes generating rows in which standard cells are to be arranged and forming tracks in the generated rows. The tracks are or correspond to imaginary lines on which wiring lines are formed afterward by a P&R tool. The EDA tool may perform the floorplan based on the heights of the generated standard cells. The EDA tool may generate a plurality of rows in which the standard cells are to be arranged. The plurality of rows may have different heights and may be arranged adjacent to each other.

According to various example embodiments, a routing-connection method of DFT instances, according to inventive concepts, may perform an algorithm based on floorplan information. According to various example embodiments, the routing-connection method may be performed between operation S210 and operation S220.

In operation S220, the EDA tool may perform power-planning in which for a power line for providing a positive supply voltage (VDD) and a power line for providing a negative supply voltage (VSS) are arranged such that power may be evenly supplied to the standard cells. According to various example embodiments, the EDA tool may include an RTL synthesis tool, a placement tool, a clock tree synthesis tool, a routing tool, a verification tool, a netlist simulation tool, or a clock domain crossing (CDC) tool. In particular, the EDA tool may include the A-star algorithm used for the DFT instance routing-connection described above.

In operation S230, the P&R tool may arrange the standard cells in the plurality of rows and may connect routing wiring lines to each other between the standard cells. For example, the P&R tool may arrange the standard cells based on information of the IC to be generated. The P&R tool may connect the standard cells to each other by forming the routing wiring lines along the tracks by using the netlist of the IC.

In operation S240, generating layout data D140 may be performed. The layout data D140 may have a format, such as GDSII, and may include geometric information of cells and interconnects.

In operation S300, optical proximity correction (OPC) may be performed. The OPC may refer to a work for forming patterns of intended shapes by correcting distortion phenomena, such as refraction and/or diffraction due to the nature of light, in a photolithography process that is included in a semiconductor process for fabricating the IC, and patterns on masks may be determined by applying the OPC to the layout data D140. In some example embodiments, the layout of the IC may be restrictively modified in operation S300, and restrictively modifying the IC in operation S300 is post-processing for optimizing the structure of the IC and may be referred to as design polishing.

In operation S400, manufacturing a mask may be performed. For example, as the OPC is applied to the layout data D140, the patterns on the masks may be defined for forming patterns of a plurality of layers, and at least one mask (or photomask) for forming patterns of each of the plurality of layers may be manufactured.

In operation S500, fabricating the IC may be performed. For example, the plurality of layers may be patterned by using the at least one mask manufactured in operation S400, thereby fabricating the IC. As shown in FIG. 10, operation S500 may include operations S510 and S520.

In operation S510, a front-end-of-line (FEOL) process may be performed. The FEOL process may refer to a process of forming individual devices, for example, a transistor, a capacitor, a resistor, and the like, on a substrate in a fabricating process of the IC. For example, the FEOL process may include planarizing and cleaning a wafer, forming a trench, forming a well, forming a gate electrode, forming a source and a drain, and/or the like.

In operation S520, a back-end-of-line (BEOL) process may be performed. The BEOL process may refer to a process of connecting the individual devices, for example, one or more of a transistor, a capacitor, a resistor, and the like, to each other in the fabricating process of the IC. For example, the BEOL process may include silicidation of source and drain regions and/or of gate regions, forming a dielectric, performing planarization, forming a hole, forming a metal layer, forming a via, forming a passivation layer, and/or the like. Next, the IC may be packaged in a semiconductor package and may be used as a component of various applications. In some example embodiments, a middle-of line (MOL) process may be performed between operation S510 and operation S520, and contacts may be respectively formed on the individual devices.

FIG. 11 is a block diagram illustrating a system-on-chip (SoC) 130, according to various example embodiments.

The SoC 130 is a semiconductor device and may include an IC according to various example embodiments. The SoC 130 refer to one chip in which complicated functional blocks, such as intellectual property (IP), performing various functions are implemented, and the SoC 130 may be designed by a method of designing an IC, according to some example embodiments. According to various example embodiments, the SoC 130 may be designed by the routing method according to inventive concepts. Referring to FIG. 11, the SoC 130 may include a modem 132, a display controller 133, a memory 134, an external memory controller 135, a central processing unit (CPU) 136, a transaction unit 137, a power management IC (PMIC) 138, and a graphics processing unit (GPU) 139, and the respective functional blocks of the SoC 130 may communicate with each other via a system bus 131.

The CPU 136, which may control all operations of the SoC 130, may control operations of the other functional blocks (that is, 132 to 139). The modem 132 may demodulate a signal received from outside the SoC 130 and/or may modulate a signal generated in the SoC 130 and transmit the signal to the outside of the SoC 130. The external memory controller 135 may control operations of transmitting data to and receiving data from an external memory device connected to the SoC 130. For example, a program and/or data stored in the external memory device may be provided to the CPU 136 or the GPU 139 under the control of the external memory controller 135. The GPU 139 may execute program instructions related to graphics processing. The GPU 139 may receive graphic data via the external memory controller 135 and may transmit graphic data processed by the GPU 139 to the outside of the SoC 130 via the external memory controller 135. The transaction unit 137 may monitor data transaction of the respective functional blocks, and the PMIC 138 may control power supplied to each functional block according to control by the transaction unit 137. The display controller 133 may control a display (or a display device) outside the SoC 130 and thus transmit data generated in the SoC 130 to the display. The memory 134 may include nonvolatile memory, such as electrically erasable programmable read-only memory (EEPROM) and/or flash memory, and/or volatile memory, such as dynamic random access memory (DRAM) and/or static random access memory (SRAM).

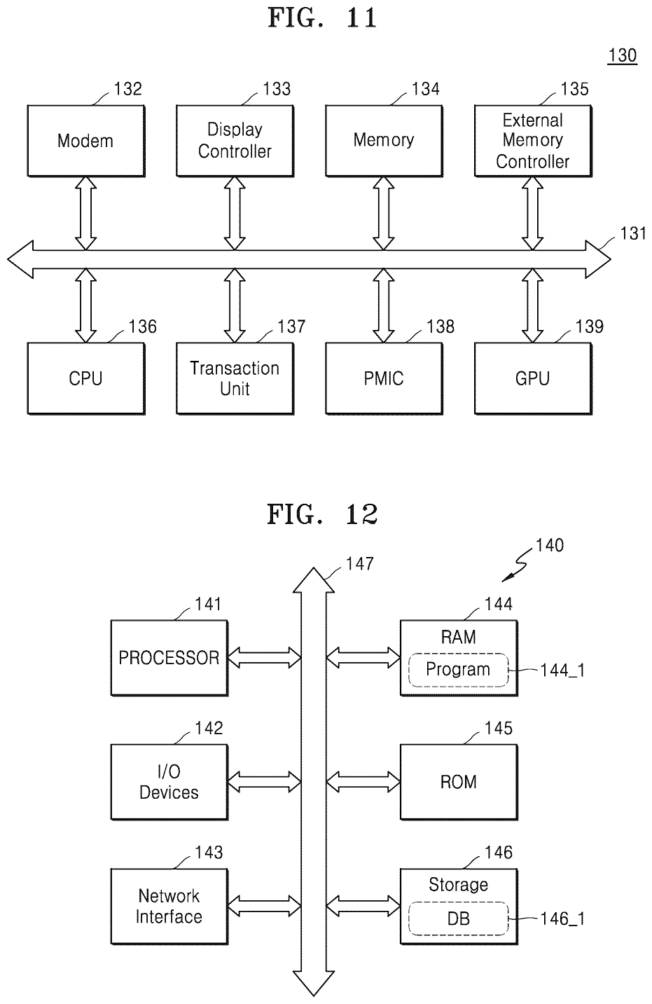

FIG. 12 is a block diagram illustrating a computing system 140 including a memory that stores a program, according to various example embodiments.

At least portions of the routing-connection method according to some example embodiments, for example, at least some of the operations of FIGS. 2 and 3, may be performed by the computing system (or computer) 140.

The computing system 140 may include a stationary computing system, such as a desktop computer, a workstation, a server, or the like, or a portable computing system, such as a laptop computer or the like. As shown in FIG. 12, the computing system 140 may include a processor 141, input/output devices 142, a network interface 143, random access memory (RAM) 144, read-only memory (ROM) 145, and a storage 146. The processor 141, the input/output devices 142, the network interface 143, the RAM 144, the ROM 145, and the storage 146 may be connected to a bus 147 and may communicate with each other via the bus 147.

The processor 141 may be referred to as a processing unit and may include at least one core, such as a micro-processor, an application processor (AP), a digital signal processor (DSP), or a GPU, which may execute any instruction set (for example, Intel Architecture-32 (IA-32), 64-bit extended IA-32, x86-64, PowerPC, Sparc, MIPS, ARM, IA-64, or the like). For example, the processor 141 may access memory, that is, the RAM 144 or the ROM 145, via the bus 147 and may execute instructions stored in the RAM 144 or the ROM 145.

The RAM 144 may store a program 144_1 for a method of designing an IC, according to various example embodiments, or at least as portion of the program 144_1, and the program 144_1 may cause the processor 141 to perform at least some of the operations of the method of FIGS. 2 and 3. That is, the program 144_1 may include a plurality of instructions that may be executed by the processor 141, and the plurality of instructions of the program 144_1 may cause the processor 141 to perform, for example, at least some of the operations in the flowchart described with reference to the method of FIGS. 2 and 3.

The storage 146 may not lose data stored in the storage 146 even when power supplied to the computing system 140 is cut off. For example, the storage 146 may include a nonvolatile memory device or may include a storage medium, such as magnetic tape, an optical disk, or a magnetic disk. In addition, the storage 146 may be removable from the computing system 140. The storage 146 may store the program 144_1 according to various example embodiments, and the program 144_1 or at least a portion of the program 144_1 may be loaded into the RAM 144 from the storage 146 before the program 144_1 is executed by the processor 141. Alternatively, the storage 146 may store a file written in a program language, and the program 144_1 generated from the file by a compiler or the like or at least a portion of the program 144_1 may be loaded into the RAM 144. In addition, as shown in FIG. 12, the storage 146 may store a database 146_1, and the database 146_1 may include information required for routing connection, for example, the cell library D120 of FIG. 10.

The storage 146 may store data to be processed by the processor 141 or data having been processed by the processor 141. That is, the processor 141 may generate data by processing data stored in the storage 146 according to the program 144_1 and may store the generated data in the storage 146. For example, the storage 146 may store the RTL data D110, the netlist data D130, and/or the layout data D140 of FIG. 10.

The input/output devices 142 may include an input device, such as a keyboard or a pointing device, and an output device, such as a display device or a printer. For example, through the input/output devices 142, a user may trigger the execution of the program 144_1 by the processor 141, may input the RTL data D110 and/or the netlist data D130 of FIG. 10, and may check the layout data D140 of FIG. 10.

The network interface 143 may provide access to a network outside of the computing system 140. For example, the network may include a large number of computing systems and communication links, and the communication links may include wired links, optical links, wireless links, or any other types of links.

In some example embodiments, the routing method described with reference to the drawings may be implemented into a computer program product. The computer program product may include a non-transitory computer-readable medium (or storage medium) including computer-readable program instructions for causing at least one processor 141 to perform a routing method. The computer-readable program instructions may include, as a non-limiting example, assembly instructions, instruction set architecture (ISA) instructions, machine instructions, machine-dependent instructions, microcode, firmware instructions, state setting data, or source code or object code written in at least one programming language.

The computer-readable medium may include any type of medium capable of non-temporarily holding and storing instructions that are executed by the at least one processor 141 or any instruction-executable device. The computer-readable medium may include, but is not limited to, an electronic storage device, a magnetic storage device, an optical storage device, an electromagnetic storage device, or any combination thereof. For example, the computer-readable medium may include a portable computer diskette, a hard disk, RAM, ROM, EEPROM, flash memory, SRAM, a compact disc (CD), a digital versatile disc (DVD), a memory stick, a floppy disk, a mechanically encoded device such as a punched card, or any combination of two or more thereof.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While various inventive concepts have been particularly shown and described with reference to embodiments thereof, it will be understood that various changes in form and details may be made therein without departing from the spirit and scope of the following claims. Example embodiments are not necessarily mutually exclusive. For example, some example embodiments may include one or more features described with reference to one or more figures, and may also include one or more other features described with reference to one or more other figures.

What is claimed is:

1. A routing method for an integrated circuit, the routing method comprising:
selecting design for testing (DFT) instances targeted by routing,
routing positions respectively corresponding to the DFT instances;
generating routing sequences for the DFT instances;
deriving a start point and an end point based on indices included in each of the routing sequences;
calculating a distance between the start point and the end point; and
selecting a routing sequence based on the calculating of the distance.

2. The routing method of claim 1, wherein the calculating of the distance between the start point and the end point comprises calculating the distance between the start point and the end point based on each of the routing sequences.

3. The routing method of claim 1, wherein the calculating of the distance between the start point and the end point comprises calculating the distance between the start point and the end point based on an A-star algorithm.

4. The routing method of claim 3, wherein the A-star algorithm comprises:
a first function of a first path from the start point to a current node; and
a second function of a second path from the current node to the end point.

5. The routing method of claim 4, wherein the second function is based on the Manhattan distance.

6. The routing method of claim 3, wherein, in the calculating of the distance between the start point and the end point by using the A-star algorithm, a path exploration of the A-star algorithm is based on upward, downward, leftward, and rightward directions, with reference to each of the routing positions.

7. The routing method of claim 1, wherein the selecting of the DFT instances targeted by routing and the routing positions respectively corresponding to the DFT instances is performed based on a consideration floorplan information.

8. The routing method of claim 1, wherein, in the selecting of the DFT instances targeted by routing and the routing positions respectively corresponding to the DFT instances, the DFT instances targeted by routing are processed with a boundary form and are configured to be bypassable.

9. A system comprising:
at least one processor; and
a memory storing machine-readable instructions, when executed by at least one processor, causing the system to perform a routing method,
wherein the routing method comprises:
selecting design for testing (DFT) instances targeted by routing;
routing positions respectively corresponding to the DFT instances;
generating routing sequences for the DFT instances;
deriving a start point and an end point based on indices included in each of the routing sequences;
calculating a distance between the start point and the end point; and
selecting a routing sequence as a result of the calculating of the distance.

10. The system of claim 9, wherein the calculating of the distance between the start point and the end point comprises calculating the distance between the start point and the end point based on each of the routing sequences.

11. The system of claim 9, wherein the calculating of the distance between the start point and the end point comprises calculating the distance between the start point and the end point by using an A-star algorithm.

12. The system of claim 11, wherein the A-star algorithm comprises:
a first function of a first path from the start point to a current node; and
a second function of a second path from the current node to the end point.

13. The system of claim 12, wherein the second function is based on the Manhattan distance.

14. The system of claim 11, wherein, in the calculating of the distance between the start point and the end point by using the A-star algorithm, a path exploration of the A-star algorithm is based on upward, downward, leftward, and rightward directions, with reference to each of the routing positions.

15. The system of claim 9, wherein the selecting of the DFT instances targeted by routing and the routing positions respectively corresponding to the DFT instances is performed based on consideration floorplan information.

16. The system of claim 9, wherein, in the selecting of the DFT instances targeted by routing and the routing positions respectively corresponding to the DFT instances, the DFT instances targeted by routing are processed with a boundary form and are configured to be bypassable.

17. A non-transitory computer-readable storage medium comprising instructions, when executed by at least one processor, cause the at least one processor to perform a routing method,
wherein the routing method comprises:
selecting design for testing (DFT) instances targeted by routing;
routing positions respectively corresponding to the DFT instances;
generating routing sequences for the DFT instances;
deriving a start point and an end point based on indices included in each of the routing sequences;
calculating a distance between the start point and the end point; and
selecting a routing sequence as a result of the calculating of the distance.

18. The non-transitory computer-readable storage medium of claim 17, wherein the calculating of the distance between the start point and the end point comprises calculating the distance between the start point and the end point based on an A-star algorithm.

19. The non-transitory computer-readable storage medium of claim 18, wherein the A-star algorithm comprises:
a first function of a first path from the start point to a current node; and
a second function of a second path from the current node to the end point.

20. The non-transitory computer-readable storage medium of claim 19, wherein the second function is based on the Manhattan distance.
